(19) United States
(12) Patent Application Publication
(10) Pub. No.: US 2025/0003841 A1
(43) Pub. Date: Jan. 2, 2025

(54) Ion Milling Device

(71) Applicant: Hitachi High-Tech Corporation, Minato-ku, Tokyo (JP)

(72) Inventors: Shota AIDA, Tokyo (JP); Hisayuki TAKASU, Tokyo (JP); Atsushi KAMINO, Tokyo (JP)

(21) Appl. No.: 18/696,487

(22) PCT Filed: Oct. 1, 2021
(86) PCT No.: PCT/JP2021/036376

§ 371 Date: Mar. 28, 2024

(51) Int. Cl. G01N 1/32; H01J 37/02

(52) U.S. Cl. CPC G01N 1/32; H01J 37/02

(57) ABSTRACT

Provided is an ion milling device capable of automatically returning to sample processing even when sample processing is interrupted due to a short circuit between an anode and a cathode. The ion milling device includes: a sample chamber 111; a sample stage 102 disposed in the sample chamber and on which a sample is placed; an ion source 101 including a first internal electrode 203 and a second internal electrode 202; a rod-shaped electrode 106 configured to be inserted into and removed from the ion source; and a power supply unit 108 connected to the first internal electrode, the second internal electrode, and the rod-shaped electrode. In a state where the rod-shaped electrode is inserted into the ion source, by the power supply unit applying a second discharge voltage between the rod-shaped electrode and the first internal electrode and the second internal electrode, the ion source generates an ion therein by a collision between an electron generated by discharge between the rod-shaped electrode and the first internal electrode or the second internal electrode and gas.

### TECHNICAL FIELD

The present invention relates to an ion milling device.

### BACKGROUND ART

An ion milling device is used to irradiate a sample (for example, metal, semiconductor, glass, or ceramic) to be observed with an electron microscope with an unfocused ion beam, and to scatter atoms on a sample surface without stress by a sputtering phenomenon, thereby polishing the sample surface and exposing an internal structure of the sample. The sample surface polished by the ion beam and the exposed internal structure of the sample are used for observation with a scanning electron microscope or a transmission electron microscope.

PTL 1 discloses that an ion milling device is provided with a gas injection method for injecting gas toward an ion gun to move attachments attached to an inside of the ion gun.

### CITATION LIST

### Patent Literature

PTL 1: WO2016/189614

### SUMMARY OF INVENTION

### Technical Problem

In the ion milling device, a high voltage is applied between an anode and a cathode inside an ion source to ionize gas introduced by generated electrons, and an acceleration voltage is applied to extract ions from the ion source to irradiate a sample. At this time, inside the ion source, the cathode is worn by a sputtering phenomenon caused by generated plasma, and a deposited film having conductivity derived from a cathode composition is formed on an inner wall surface of the anode. The deposited film grows as a device operating time elapses. The grown deposited film is peeled off in a needle shape to short-circuit the anode and the cathode, making it impossible to generate ions. Therefore, it is necessary to disassemble the ion source to remove a short-circuited portion. Therefore, in the ion milling device in the related art, every time a short circuit occurs, it is necessary to interrupt sample processing and remove the deposited film.

In PTL 1, it is possible to remove the deposited film without disassembling the ion source by using a gas injection method. However, it is necessary to once open a sample chamber to an atmosphere and then evacuate the sample chamber again after recovery from the short circuit, which reduces processing efficiency.

For process management in a semiconductor manufacturing process, when it is assumed that an ion milling device is disposed in a line of a factory and surface polishing of a sample observed with an electron microscope or processing for exposing an internal structure is performed, it is desirable that the ion milling device automatically processes a large number of samples contiguously. Automatic milling processing of a large number of samples contiguously involves contiguous ion beam irradiation for a long time. Therefore, there is a demand for an ion milling device capable of automatically removing a short circuit even when a short circuit occurs between an anode and a cathode and returning to a processing treatment in a short time.

### Solution to Problem

An ion milling device that is an embodiment of the invention includes: a sample chamber; a sample stage disposed in the sample chamber and on which a sample is placed; an ion source including a first internal electrode, a second internal electrode, and an acceleration electrode; a rod-shaped electrode configured to be inserted into and removed from the ion source; and a power supply unit connected to the first internal electrode, the second internal electrode, the acceleration electrode, and the rod-shaped electrode. In a state where the rod-shaped electrode is retracted from the ion source, by the power supply unit applying a first discharge voltage between the first internal electrode and the second internal electrode and an acceleration voltage between the first internal electrode and the acceleration electrode, the ion source accelerates, by the acceleration voltage, an ion generated by a collision between gas and an electron generated by discharge between the first internal electrode and the second internal electrode, and emits the ion as an unfocused ion beam directed toward the sample, and in a state where the rod-shaped electrode is inserted into the ion source, by the power supply unit applying a second discharge voltage between the rod-shaped electrode and the first internal electrode and the second internal electrode, the ion source generates an ion therein by a collision between gas and an electron generated by discharge between the rod-shaped electrode and the first internal electrode or the second internal electrode.

An ion milling device that is another embodiment of the invention includes: a sample chamber; a sample stage disposed in the sample chamber and on which a sample is placed; an ion source configured to accelerate, by an acceleration electrode, an ion generated by an electron generated by discharge between an anode and a cathode, and emit the ion as an unfocused ion beam directed toward the sample; a power supply unit connected to the anode, the cathode, and the acceleration electrode; a rod-shaped member configured to be inserted into and removed from the ion source and provided with a brush at a tip end thereof; and a control unit configured to, when a short circuit between the anode and the cathode is detected during processing of the sample by the ion beam, cause the power supply unit to stop applying a discharge voltage applied between the anode and the cathode and an acceleration voltage applied between the anode and the acceleration electrode, insert the rod-shaped member into the ion source, and cause the brush to remove a short-circuited portion between the anode and the cathode.

### Advantageous Effects of Invention

Provided is an ion milling device capable of automatically returning to sample processing even when sample processing is interrupted due to a short circuit between an anode and a cathode. Accordingly, it is possible to automate continuous sample processing for a long time.

Other problems and novel features will become apparent from description of this description and the accompanying drawings.

### BRIEF DESCRIPTION OF DRAWINGS

FIG. 1A is a schematic diagram showing main parts of an ion milling device in Embodiment 1.

FIG. 1B is a diagram showing a positional relationship between a shutter and an ion source.

FIG. 1C is a diagram showing a positional relationship between the shutter and the ion source.

FIG. 2A is a schematic diagram showing the ion source and a power supply circuit that applies a control voltage to an internal electrode of the ion source.

FIG. 2B is a schematic diagram showing the ion source and the power supply circuit that applies a control voltage to an internal electrode of the ion source.

FIG. 3 is a schematic diagram showing a state in which a shaft is inserted into the ion source.

FIG. 4 is a flowchart showing a series of operations from a start to an end of sample processing by the ion milling device in Embodiment 1.

FIG. 5 is a schematic diagram showing main parts of an ion milling device in Embodiment 2.

FIG. 6 is a flowchart showing a series of operations from a start to an end of sample processing by the ion milling device in Embodiment 2.

FIG. 7A is a schematic diagram showing a state in which a shaft with a brush is inserted into an ion source in an ion milling device in Embodiment 3.

FIG. 7B is a shaft rotation source viewed from a Y direction.

FIG. 8 is a flowchart showing a series of operations from a start to an end of sample processing by the ion milling device in Embodiment 3.

### DESCRIPTION OF EMBODIMENTS

Hereinafter, embodiments of the invention will be described with reference to the drawings.

### Embodiment 1

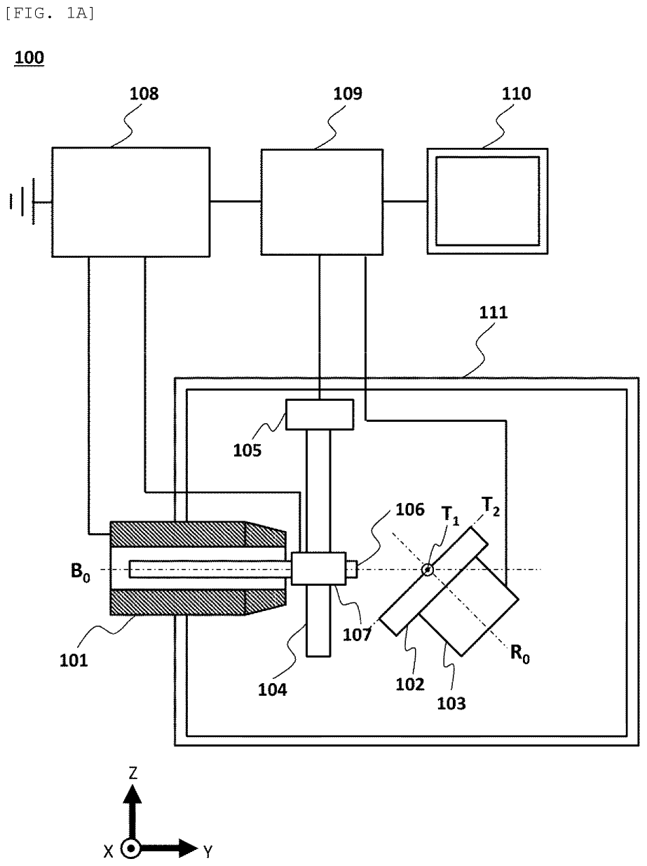

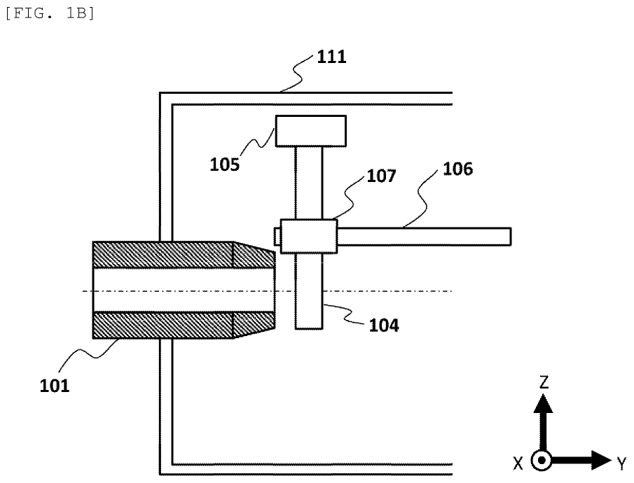

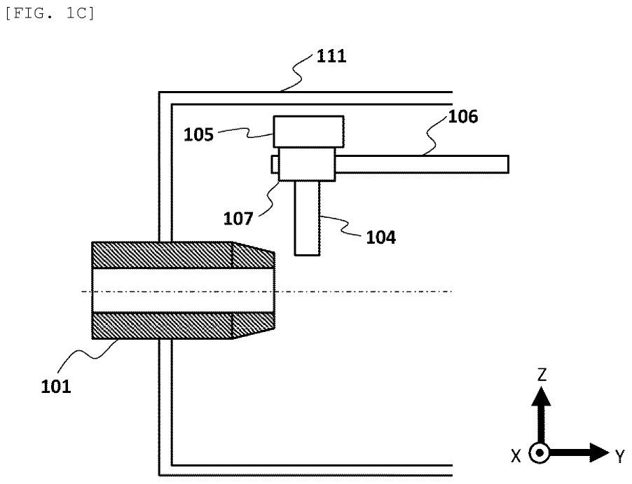

FIG. 1A is a schematic diagram of main parts of an ion milling device 100 in Embodiment 1 from a side. In FIG. 1A, a vertical direction is shown as a Z direction. The ion milling device 100 includes, as main components, an ion source 101, a sample stage 102, a sample stage drive source 103, a shutter 104, a shutter drive source 105, a shaft (rod-shaped electrode) 106 that functions as an external electrode and can be inserted into and removed from the ion source 101, a shaft drive source 107, a power supply unit 108, a control unit 109, a display unit 110, and a sample chamber 111.

The ion milling device 100 is used as a pretreatment device for observing a surface or a cross-section of a sample with a scanning electron microscope or a transmission electron microscope. The ion source for such a pretreatment device often adopts a Penning method effective for reducing a size of a structure. In the embodiment as well, the ion source 101 adopts the Penning method, and irradiation with an unfocused ion beam is performed from the ion source 101 toward a sample placed on the sample stage 102. An output of the ion beam is mainly controlled by a control voltage (acceleration voltage, discharge voltage) applied to an internal electrode of the ion source 101 by the power supply unit 108 and a flow rate of argon gas supplied to the ion source 101.

The sample stage 102 on which the sample is placed is attached to the sample chamber 111 via the sample stage drive source 103 that positions the sample stage 102. The sample stage drive source 103 rotates the sample stage 102 about a rotation axis R₀. The sample stage drive source 103 is attached to the sample chamber 111 so that a position of the sample stage 102 can be adjusted in each of an X direction, a Y direction, and the Z direction, and an orientation of the sample stage 102 with respect to an ion beam center axis B₀ can be adjusted in each of an angular direction of an XZ plane (a rotation direction around a T₁ axis) and an angular direction of a YZ plane (a rotation direction around a T₂ axis).

The shutter 104 that blocks irradiation to the sample with the ion beam is provided in front of the ion source 101. Here, a direction in which the ion beam is emitted is referred to as a front of the ion source, and corresponds to the Y direction in an example in FIG. 1A. The shutter 104 is driven by the shutter drive source 105. The shutter 104 is configured to move in the Z direction, and a positional relationship between the shutter 104 and the ion source 101 is shown in FIGS. 1B and 1C. FIG. 1B shows a state in which the shaft 106 is retracted from the ion source 101 and the shutter 104 blocks the ion beam emitted from the ion source 101. FIG. 1C shows a state in which the shutter 104 is retracted from a front of the ion source 101, allowing milling processing of the sample with the ion beam.

In this example, the shaft drive source 107 is provided in the shutter 104, and the shutter drive source 105 is shared as a drive source that moves a position of the shaft 106 in the Z direction in conjunction with the shutter 104. Therefore, regardless of drive states of the shutter drive source 105 and the shaft drive source 107, the shaft 106 is positioned in the same YZ plane as the ion beam center axis B₀, simplifying a mechanism. The above is an example, and the invention is not limited to the mechanism shown in FIGS. 1A to 1C. For example, a retraction direction of the shutter 104 may not be the Z direction, and a dedicated drive source for driving the shaft 106 independently of the shutter 104 may be provided.

Sample processing by the ion milling device in the embodiment is performed as follows. The shutter 104 blocks irradiation with an unstable ion beam from the ion source 101 to the sample until a current value of the ion beam is stabilized in a preset range. The shutter 104 at this time is in a position shown in FIG. 1B. After the current value of the ion beam is stabilized, the shutter 104 is retracted from the front of the ion source 101 by the shutter drive source 105 (FIG. 1C), and thus ion beam irradiation to the sample on the sample stage 102 is started.

When a short circuit occurs inside the ion source 101 during the sample processing, the position of the shaft 106 is moved by the shutter drive source 105 so that the ion source 101 and the shaft 106 are coaxially disposed. When the ion source 101 and the shaft 106 are coaxially disposed, the shaft drive source 107 moves the shaft 106 in the Y direction and inserts the shaft 106 into the ion source 101. A state of the shutter 104 and the shaft 106 at this time is a state in FIG. 1A. Although details are to be described later, to remove a short-circuited portion, the power supply unit 108 applies a high voltage between the shaft 106 inserted into the ion source 101 and the internal electrode of the ion source 101.

The above control is performed by the control unit 109, and a status of the ion source 101 such as occurrence of a short circuit or recovery from a short circuit can be checked in real time from the display unit 110.

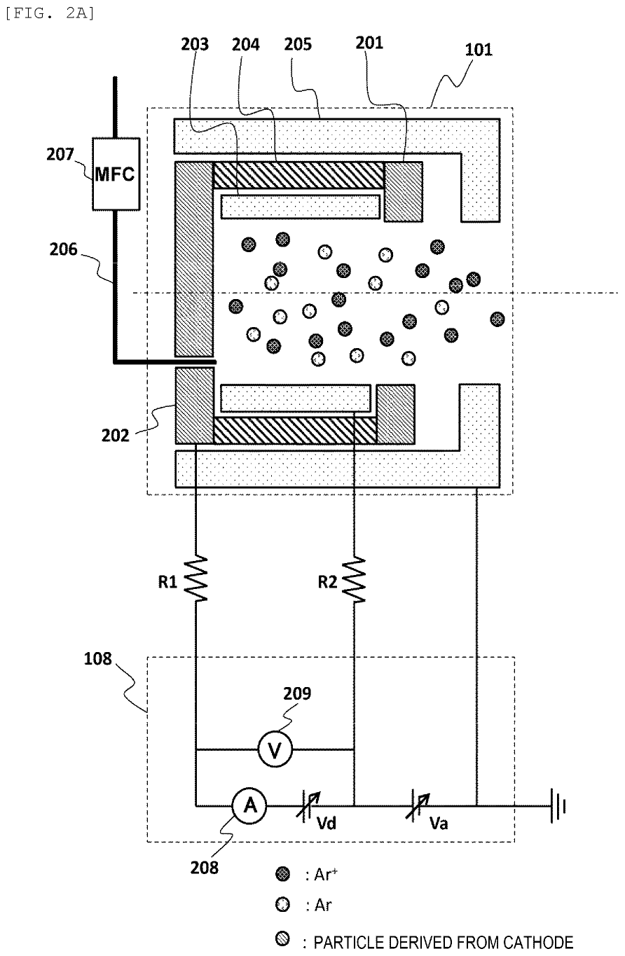

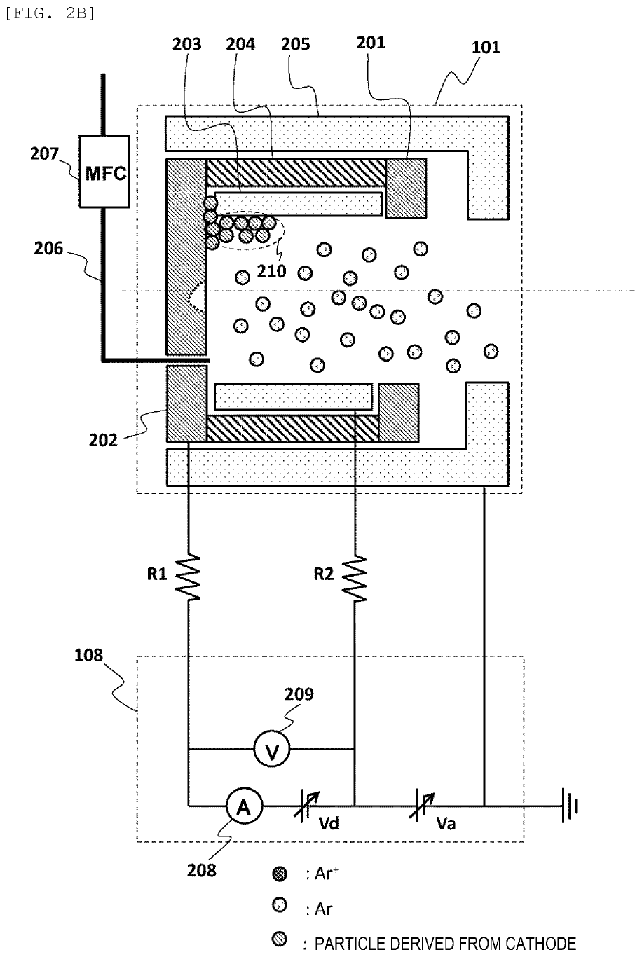

FIG. 2A is a schematic diagram showing the ion source 101 adopting the Penning method and a power supply circuit that applies a control voltage to the internal electrode of the ion source 101. The power supply circuit is a part of the power supply unit 108.

The ion source 101 includes a first cathode 201, a second cathode (second internal electrode) 202, an anode (first internal electrode) 203, a permanent magnet 204, an acceleration electrode 205, and a gas pipe 206. The gas pipe 206 is provided with a mass flow controller 207 that controls a flow rate of argon gas supplied to the ion source 101.

Inside the ion source 101, the first cathode 201 and the second cathode 202 have the same potential when a voltage is applied via the permanent magnet 204. The anode 203 is disposed between the first cathode 201 and the second cathode 202. Electrons are generated when a discharge voltage Vd (first discharge voltage) is applied between the cathodes 201, 202 and the anode 203 from the power supply unit 108. Electrons stay inside the ion source 101 while being spirally moved by the permanent magnet 204, and collide with the argon gas injected from the gas pipe 206 to generate argon ions. An acceleration voltage Va is applied from the power supply unit 108 between the anode 203 and the acceleration electrode 205, and the generated argon ions are attracted to the acceleration electrode 205 and emitted as an ion beam. The acceleration electrode 205 is set to a reference potential (GND), and a potential for applying a control voltage to the cathodes 201, 202 and the anode 203 is supplied from the power supply unit 108. Here, to prevent an operation of the ion source 101 from being adversely affected by a rapid fluctuation in the potential applied to the cathode and the anode, protective resistors R1 and R2 are provided. Instead of the protective resistor, a protective circuit that cuts off a voltage application when an abnormality occurs may be provided.

The power supply circuit is provided with an ammeter 208 and a voltmeter 209 between the anode 203 and the first cathode 201 and the second cathode 202. The ammeter 208 measures a discharge current flowing between the cathode and the anode during discharge. The voltmeter 209 measures a discharge voltage actually applied between the cathode and the anode during discharge. A discharge current value measured by the ammeter 208 and a discharge voltage value measured by the voltmeter 209 are also output to the control unit 109. The control unit 109 may use the discharge current value and the discharge voltage value to monitor an output state of the ion beam and display the discharge current value and the discharge voltage value on the display unit 110.

As the discharge for generating argon ions is repeated, the second cathode 202 is worn out by being sputtered by argon ions. Sputtered particles derived from the cathode due to wear are deposited on an inner wall surface of the anode to form a deposited film 210. The deposited film 210 is eventually peeled off in a needle shape to short-circuit the anode and the cathode. FIG. 2B shows the ion source 101 in which the anode and the cathode are short-circuited. The short circuit eliminates a potential difference between the anode and cathode, stopping the discharge and interrupting sample processing.

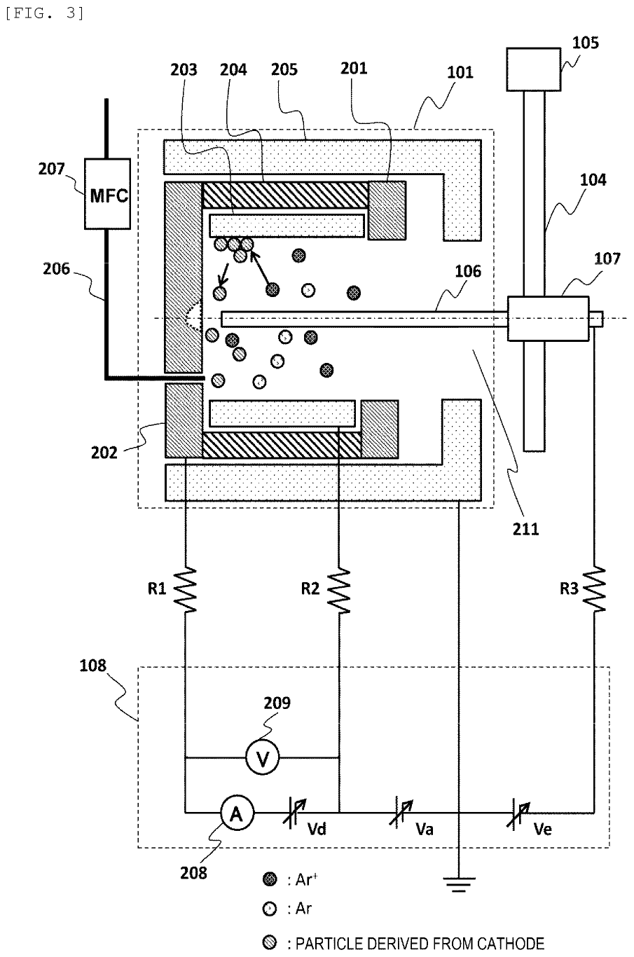

FIG. 3 is a schematic diagram showing a state in which the shaft 106 is inserted into the ion source 101 to remove the short-circuited portion after occurrence of the short circuit between the anode and the cathode shown in FIG. 2B. The control unit 109 detects the occurrence of the short circuit between the anode and the cathode, for example, when a discharge voltage value measured by the voltmeter 209 abnormally decreases. In response to the detection of the occurrence of the short circuit, the control unit 109 stops applying a control voltage to the ion source 101, and moves the shutter 104 by the shutter drive source 105 to place the shaft 106 coaxially with an opening 211 of the acceleration electrode 205. A reason for the coaxial disposition is to prevent the shaft 106 from coming into contact with the internal electrode of the ion source 101 due to a control error or the like. Thereafter, the shaft 106 is inserted into the ion source 101 by the shaft drive source 107. The power supply unit 108 includes a power supply circuit that applies a voltage Ve between the shaft 106 and the acceleration electrode 205. A protective resistor R3 is provided in consideration of a possibility that the voltage applied to the shaft 106 rapidly fluctuates. Instead of the protective resistor R3, a protective circuit that interrupts the application of a voltage when an abnormality occurs may be provided.

After the shaft 106 is inserted into the ion source 101, the argon gas introduced into the ion source 101 is ionized by the power supply unit 108 applying a high voltage (second discharge voltage) between the shaft 106 and the short-circuited cathodes 201, 202 and anode 203. Here, the voltage Ve is set to a voltage value having a negative polarity with respect to the reference potential, and the discharge voltage Vd and acceleration voltage Va are set to 0 V, so that a high voltage (second discharge voltage) is applied between the short-circuited cathodes 201, 202 and the anode 203, and discharge occurs. At this time, the shaft 106 functions as an anode, and the cathodes 201, 202 and the anode 203 function as cathodes. In the description of the embodiment, the internal electrode is referred to as the cathodes 201, 202 and the anode 203 based on a function at the time of ion beam emission, and the description is simplified. The second discharge voltage may be a sum of the negative voltage Ve and the positive voltage Va to cause discharge.

The argon ions scrape the deposited film 210 by a sputtering phenomenon, thereby recovering from the short circuit between the anode and the cathode. The recovery from the short circuit can be determined by a voltage applied to the voltmeter 209 when the power supply unit 108 applies a predetermined voltage between the anode and the cathode. When recovery from the short circuit is detected, the control unit 109 retracts the shaft 106 from the ion source 101.

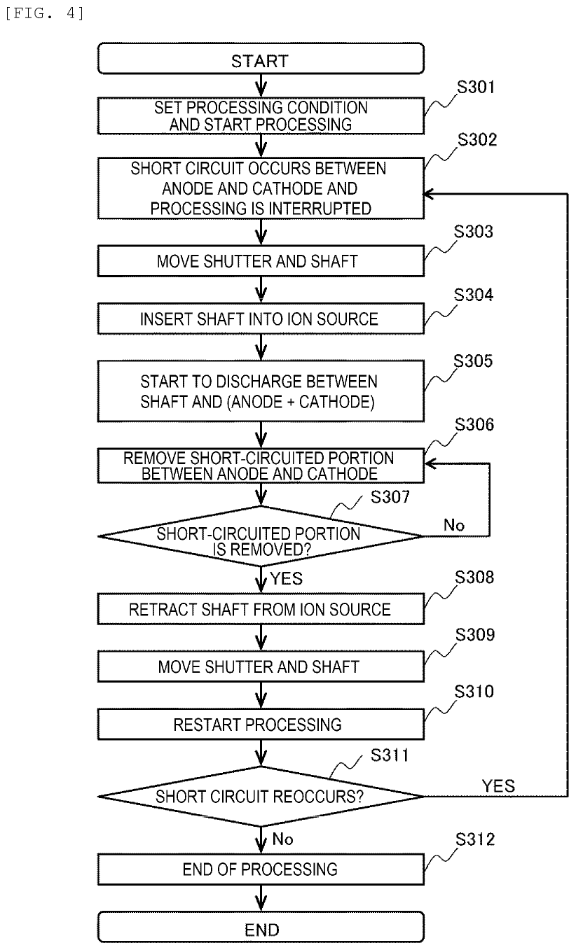

A flowchart shown in FIG. 4 shows a series of operations from a start to an end of sample processing by the ion milling device 100 in Embodiment 1. Processing from detection of a short circuit during the sample processing to a restart of processing is automatically performed by the control unit 109. The operation in each step is to be described below.

S301: Sample processing conditions of the ion milling device 100 are set, and sample processing is started. The sample processing conditions include an acceleration voltage of the ion source 101, a discharge voltage, a supply amount of argon gas, a position of the sample stage, a sample processing time, and the like.

S302: During the sample processing, the control unit 109 monitors a discharge current value by the ammeter 208 and a discharge voltage value by the voltmeter 209. When a short circuit between the anode and the cathode is detected based on the discharge voltage value measured by the voltmeter 209, the control unit 109 stops applying the discharge voltage Vd and the acceleration voltage Va from the power supply unit 108, and interrupts the sample processing. At this time, the control unit 109 continues to supply argon gas to the ion source 101.

S303: The control unit 109 drives the shutter drive source 105 to move the shaft 106 forward of the ion source 101. At this time, the shaft 106 and the ion source 101 are coaxially disposed.

S304: The control unit 109 drives the shaft drive source 107 to insert the shaft 106 into the ion source 101.

S305: By applying the voltage Ve between the short-circuited anode 203 and cathodes 201, 202 and the shaft 106, discharge is caused between the shaft, the anode, and the cathodes. Accordingly, the argon gas introduced into the ion source 101 is ionized.

S306: A short-circuited portion between the anode and the cathode is removed by a sputtering phenomenon caused by generated argon ions.

S307: After the voltage Ve is applied to the shaft 106 for a certain period of time, a predetermined voltage is applied between the anode 203 and the cathodes 201, 202, and it is confirmed that the short-circuited portion between the anode and the cathode is removed. Whether the short-circuited portion is removed can be determined based on whether a potential difference corresponding to the applied voltage is measured between the anode and the cathode by the voltmeter 209. When the short-circuited portion is not removed, step S306 is subsequently executed.

S308: After the short circuit between the anode and the cathode is recovered, the control unit 109 stops the voltage application from the power supply unit 108 to the shaft 106, drives the shaft drive source 107, and retracts the shaft 106 from the ion source 101.

S309: The control unit 109 drives the shutter drive source 105 to retract the shaft 106 from the front of the ion source 101.

S310: The interrupted sample processing is restarted according to the sample processing condition set in step S301.

S311: When a short circuit between the anode and the cathode reoccurs during the sample processing, the process returns to step S302 to perform a short circuit removal operation between the anode and the cathode.

S312: When the sample processing time set in step S301 is reached, the sample processing is ended.

### Embodiment 2

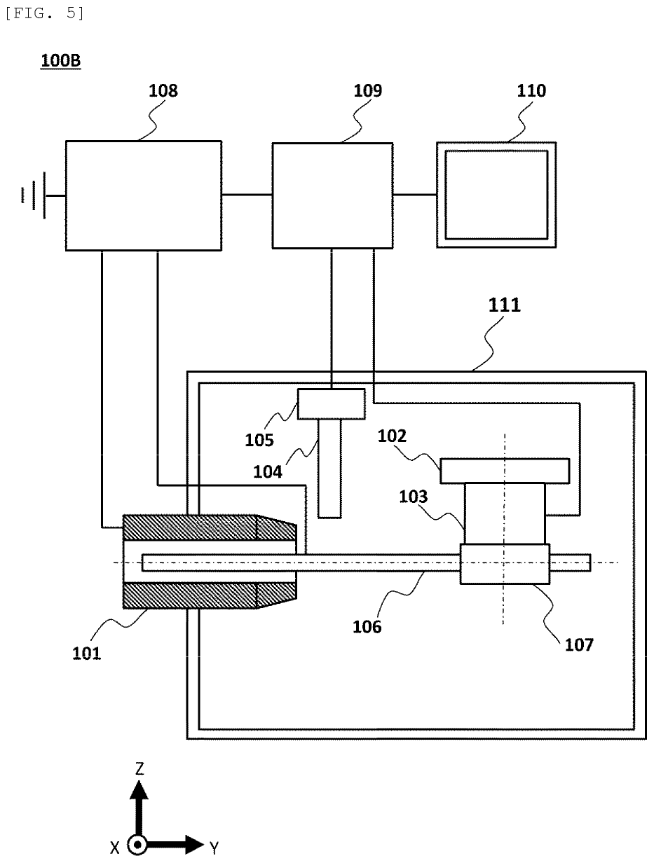

FIG. 5 is a schematic diagram of main parts of an ion milling device 100B in Embodiment 2 from a side. In the ion milling device 100B, the shaft 106 is provided on the sample stage 102 instead of the shutter 104. Components having similar functions as those in Embodiment 1 are denoted by the same reference signs, and redundant description thereof is omitted. The shaft drive source 107 for moving the shaft 106 in the Y direction is provided on the sample stage 102. Accordingly, when the shaft drive source 107 is mounted, a drive mechanism of the sample stage drive source 103 for driving the sample stage 102 is shared, and the mechanism can be simplified.

A difference from Embodiment 1 is a process of inserting the shaft 106 when a short circuit occurs inside the ion source 101. In Embodiment 2, since the shaft 106 is provided on the sample stage 102, a position and a posture of the sample stage 102 change to insert the shaft 106 into the ion source 101. Therefore, after storing position information and the posture (tilt) information on the sample stage when a short circuit occurs, an insertion operation of the shaft 106 into the ion source 101 is performed, and after short circuit removal, a position and a posture of the sample stage 102 are recovered to a state before a short circuit removal operation based on the stored position information and posture information on the sample stage.

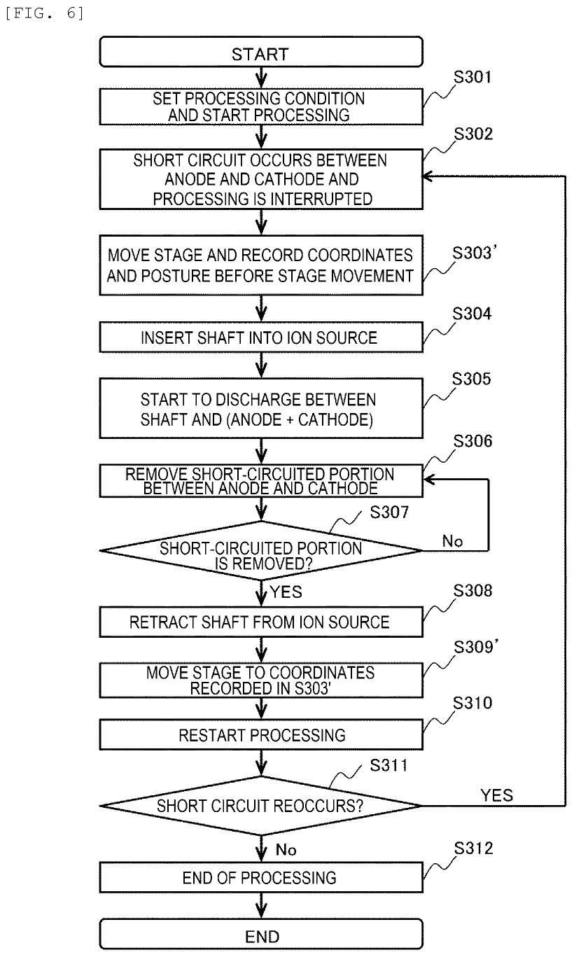

A flowchart shown in FIG. 6 shows a series of operations from a start to an end of sample processing of the ion milling device 100B in Embodiment 2. The same steps as those in the flowchart of Embodiment 1 (FIG. 4) are denoted by the same reference signs, and redundant description is omitted.

After the processing is interrupted due to the occurrence of the short circuit between the anode and the cathode (S302), the control unit 109 drives the sample stage drive source 103 so that the shaft 106 and the ion source 101 are coaxially disposed. By the operation, the position and the posture of the sample stage 102 change from a state before the processing is interrupted. Therefore, state information on the sample stage before driving the sample stage drive source 103 is recorded (S303′). The state information is information for restoring the sample stage 102 to the state before the processing is interrupted after recovery from the short circuit, and includes position coordinates (x, y, z) of the sample stage 102 and, if necessary, posture information on the sample stage 102 (an inclination θ₁ about the T₁ axis and an inclination θ₂ about the T₂ axis).

After the sample stage 102 is driven, the shaft 106 is inserted into the ion source 101 by the shaft drive source 107 in the same manner as in Embodiment 1, and a short-circuited portion between the anode and the cathode is removed. After the recovery from the short circuit, the shaft 106 is retracted from the ion source 101 (S308), and the sample stage 102 is recovered to a state when the processing is interrupted based on the state information recorded in step S303′ (S309′). Specifically, the control unit 109 moves the sample stage 102 to the recorded position coordinates (x, y, z), and drives the sample stage drive source 103 to tilt the sample stage 102 according to recorded posture information.

### Embodiment 3

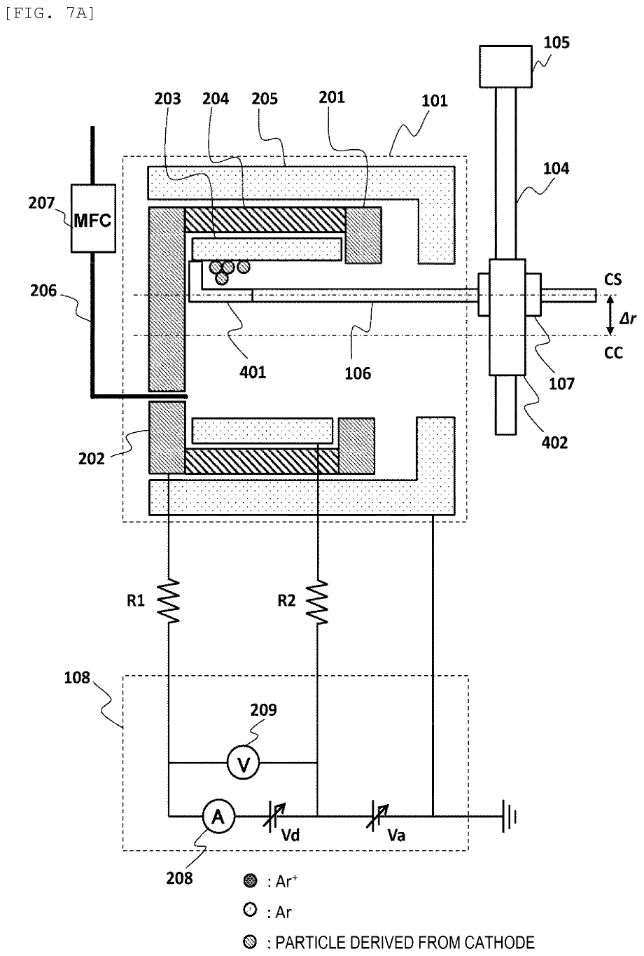

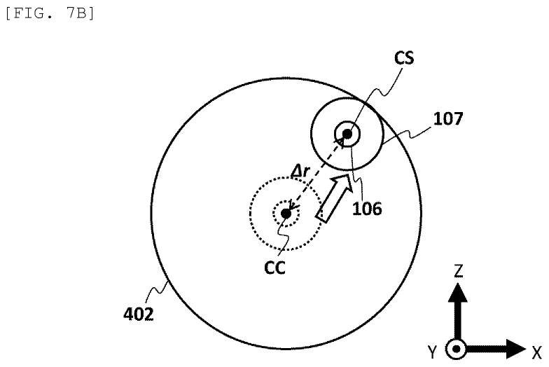

FIG. 7A is a schematic diagram showing the ion source 101 of an ion milling device in Embodiment 3 and a power supply circuit that applies a control voltage to the internal electrode of the ion source 101. A method for removing a short-circuited portion between the anode and the cathode is different from those of Embodiments 1 and 2.

A brush 401 is provided at a tip end of the shaft (rod-shaped member) 106. The shaft 106 is attached to a shaft rotation source 402 via the shaft drive source 107. Unlike the shaft 106 in Embodiment 1, the shaft 106 in Embodiment 3 does not function as the external electrode, but functions as a support member for the brush 401. The shaft rotation source 402 viewed from the Y direction is shown in FIG. 7B. The shaft rotation source 402 rotates about a rotation center CC, and the shaft 106 also rotates as the shaft rotation source 402 rotates. The shaft rotation source 402 is configured to move holding positions of the shaft 106 and the shaft drive source 107 from the rotation center CC toward an outer circumferential direction of the shaft rotation source 402. The shaft rotation source 402 causes the holding position to be eccentric in the outer circumferential direction by Ar from the rotation center CC. At this time, as shown in FIG. 7A, the brush 401 is in contact with inner wall surfaces of the second cathode 202 and the anode 203. In this state, when the shaft rotation source 402 rotates the shaft 106 about the rotation center CC, the brush 401 rotates along the inner wall surfaces of the second cathode 202 and the anode 203 to remove a deposited film of sputtered particles.

Here, the brush 401 is made of a material having low rigidity, such as resin or rubber, so as not to damage the second cathode 202 or the anode 203 in contact therewith, and has a shape (L-shape) including a portion that extends outward. Since the brush 401 has the L-shape, an outermost periphery of the brush 401 that can be reached when the shaft 106 is rotated can be located outside a region where the shaft 106 is rotated. Accordingly, the brush 401 can be brought into contact with the inner wall surface of the anode 203 without bringing the shaft 106 into contact with the acceleration electrode 205. Although FIG. 7A shows an L-shaped brush, a shape of the brush 401 is not limited to an L-shape as long as the brush 401 can come into contact with the inner wall surface of the anode 203 without the shaft 106 coming into contact with the acceleration electrode 205. In an example in FIG. 7A, an example in which the shaft rotation source 402 is provided on the shutter 104 as in Embodiment 1 is shown, but the shaft rotation source 402 may be provided on the sample stage 102 as in Embodiment 2.

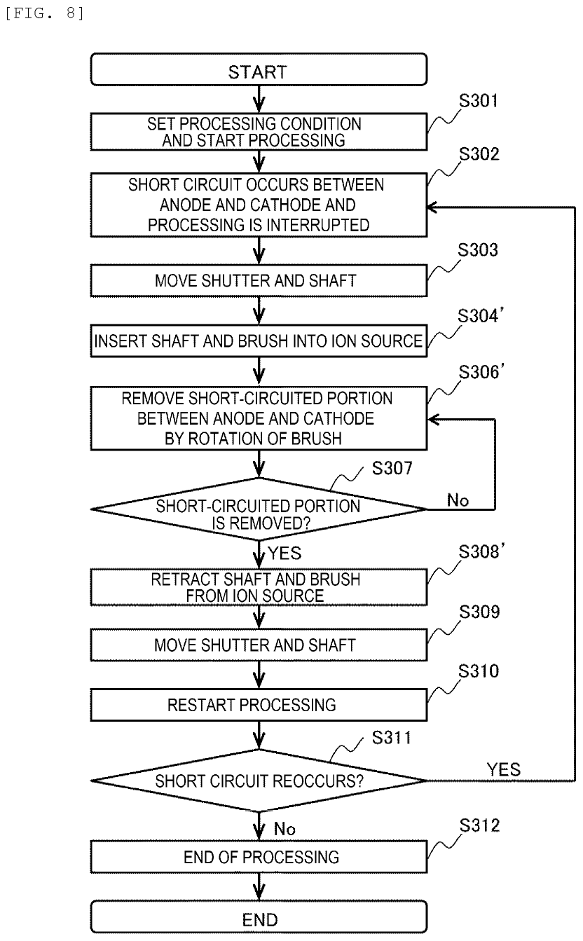

A flowchart shown in FIG. 8 shows a series of operations from a start to an end of sample processing of the ion milling device in Embodiment 3. The same steps as those in the flowchart of Embodiment 1 (FIG. 4) and the flowchart of Embodiment 2 (FIG. 6) are denoted by the same reference signs, and redundant description is omitted.

When an occurrence of a short circuit between the anode and the cathode is detected, the processing is interrupted (S302). In Embodiment 3, the control unit 109 may stop supply of argon gas to the ion source 101. Thereafter, the control unit 109 drives the shutter drive source 105 to move the shaft 106 forward of the ion source 101 (S303). At this time, the shaft 106 is positioned at the rotation center CC of the shaft rotation source 402, and the rotation center CC of the shaft rotation source 402 is disposed on a central axis of the ion source 101. Accordingly, the shaft 106 and the ion source 101 are coaxially disposed.

In this state, the control unit 109 drives the shaft drive source 107, inserts the shaft 106 into the ion source 101 until the brush 401 comes into contact with the second cathode 202, and then eccentrically moves (by Ar) the holding position of the shaft 106 on the shaft rotation source 402 until the brush 401 comes into contact with the anode 203 (S304′). A central axis of the eccentric shaft 106 is represented as a central axis CS in FIGS. 7A and 7B. Thereafter, the control unit 109 causes the shaft rotation source 402 to rotate the shaft 106 about the rotation center CC, thereby rotating the brush 401 along the inner wall surfaces of the second cathode 202 and the anode 203 and removing the deposited film of the sputtered particles (S306′). After the brush 401 is rotated for a predetermined time set in advance, it is confirmed that a short-circuited portion between the anode and the cathode is removed (S307). The shaft is retracted from the ion source. After the recovery from the short circuit between the anode and the cathode, the control unit 109 drives the shaft drive source 107 to retract the shaft 106 from the ion source 101 (S308′).

Although the invention made by the present inventor is specifically described based on embodiments, the invention is not limited to the embodiments described above, and various modifications can be made without departing from the gist of the invention. For example, the shaft used as the external electrode in Embodiment 1 may have a structure including an insulator so that a voltage is applied only to the tip end of the shaft inserted into the ion source 101 to efficiently cause a sputtering phenomenon caused by argon ions only at a short-circuited portion.

### REFERENCE SIGNS LIST

100, 100B: ion milling device
101: ion source
102: sample stage
103: sample stage drive source
104: shutter
105: shutter drive source
106: shaft
107: shaft drive source
108: power supply unit
109: control unit
110: display unit
111: sample chamber
201: first cathode
202: second cathode
203: anode
204: permanent magnet
205: acceleration electrode
206: gas pipe
207: mass flow controller
208: ammeter
209: voltmeter
210: deposited film
211: opening
401: brush
402: shaft rotation source

1. An ion milling device comprising:
a sample chamber;
a sample stage disposed in the sample chamber and on which a sample is placed;
an ion source including a first internal electrode, a second internal electrode, and an acceleration electrode;
a rod-shaped electrode configured to be inserted into and removed from the ion source; and
a power supply unit connected to the first internal electrode, the second internal electrode, the acceleration electrode, and the rod-shaped electrode, wherein
in a state where the rod-shaped electrode is retracted from the ion source, by the power supply unit applying a first discharge voltage between the first internal electrode and the second internal electrode and an acceleration voltage between the first internal electrode and the acceleration electrode, the ion source accelerates, by the acceleration voltage, an ion generated by a collision between gas and an electron generated by discharge between the first internal electrode and the second internal electrode, and emits the ion as an unfocused ion beam directed toward the sample, and
in a state where the rod-shaped electrode is inserted into the ion source, by the power supply unit applying a second discharge voltage between the rod-shaped electrode and the first internal electrode and the second internal electrode, the ion source generates an ion therein by a collision between gas and an electron generated by discharge between the rod-shaped electrode and the first internal electrode or the second internal electrode.

2. The ion milling device according to claim 1, further comprising:
a control unit configured to, when a short circuit between the first internal electrode and the second internal electrode is detected during processing of the sample by the ion beam, cause the power supply unit to stop applying the first discharge voltage and the acceleration voltage, and cause the power supply unit to apply the second discharge voltage after the rod-shaped electrode is inserted into the ion source.

3. The ion milling device according to claim 2, wherein
the control unit continues to supply the gas to the ion source even after the power supply unit stops applying the first discharge voltage and the acceleration voltage.

4. The ion milling device according to claim 3, wherein
the control unit is configured to, when removal of a short-circuited portion between the first internal electrode and the second internal electrode is detected, cause the power supply unit to stop applying the second discharge voltage, and after the rod-shaped electrode is retracted from the ion source, cause the power supply unit to restart application of the first discharge voltage and the acceleration voltage.

5. The ion milling device according to claim 3, wherein
the power supply unit includes a voltmeter configured to measure a potential difference between the first internal electrode and the second internal electrode, and
the control unit is configured to detect a short circuit or recovery from a short circuit between the first internal electrode and the second internal electrode based on the potential difference measured by the voltmeter.

6. The ion milling device according to claim 4, further comprising:
a first drive source configured to move the rod-shaped electrode forward of an opening through which the ion source emits the ion beam; and
a second drive source configured to insert the rod-shaped electrode moved forward of the opening into the ion source, wherein
the control unit inserts and removes the rod-shaped electrode by the first drive source and the second drive source.

7. The ion milling device according to claim 6, further comprising:
a shutter configured to block irradiation with the ion beam to the sample; and
a shutter drive source configured to drive the shutter, wherein
the first drive source is shared with the shutter drive source.

8. The ion milling device according to claim 6, further comprising:
a sample stage drive source configured to position the sample stage, wherein
the first drive source is shared with the sample stage drive source.

9. The ion milling device according to claim 8, wherein
the control unit stores state information on the sample stage before starting an operation of inserting the rod-shaped electrode into the ion source, and after the rod-shaped electrode is retracted from the ion source, restores, based on the state information, the sample stage to a state before starting the operation of inserting the rod-shaped electrode into the ion source.

10. The ion milling device according to claim 9, wherein
the state information includes a position coordinate and posture information on the sample stage.

11. An ion milling device comprising:
a sample chamber;
a sample stage disposed in the sample chamber and on which a sample is placed;
an ion source configured to accelerate, by an acceleration electrode, an ion generated by an electron generated by discharge between an anode and a cathode, and emit the ion as an unfocused ion beam directed toward the sample;
a power supply unit connected to the anode, the cathode, and the acceleration electrode;
a rod-shaped member configured to be inserted into and removed from the ion source and provided with a brush at a tip end thereof; and
a control unit configured to, when a short circuit between the anode and the cathode is detected during processing of the sample by the ion beam, cause the power supply unit to stop applying a discharge voltage applied between the anode and the cathode and an acceleration voltage applied between the anode and the acceleration electrode, insert the rod-shaped member into the ion source, and cause the brush to remove a short-circuited portion between the anode and the cathode.

12. The ion milling device according to claim 11, wherein
the control unit causes, when the removal of the short-circuited portion between the anode and the cathode is detected, the power supply unit to restart application of the discharge voltage and the acceleration voltage after the rod-shaped member is retracted from the ion source.

13. The ion milling device according to claim 12, further comprising:
a first drive source configured to move the rod-shaped member forward of an opening through which the ion source emits the ion beam;
a second drive source configured to insert the rod-shaped member moved forward of the opening into the ion source; and
a rotation source configured to hold the rod-shaped member and rotate the rod-shaped member about a rotation center, wherein
the control unit inserts, in a state where the rod-shaped member is held about the rotation center of the rotation source, the rod-shaped member into the ion source by the first drive source and the second drive source until the rod-shaped member comes into contact with the cathode.

14. The ion milling device according to claim 13, wherein
the rotation center of the rod-shaped member is disposed on a central axis of the ion source, and
after the rod-shaped member is inserted into the ion source, the control unit eccentrically moves a holding position of the rod-shaped member by the rotation source until the brush comes into contact with the cathode, and rotates the rod-shaped member around the rotation center by the rotation source.

15. The ion milling device according to claim 14, wherein
the brush has a shape including a portion that extends outward from the rod-shaped member.
